(19) United States
(12) Patent Application Publication
(10) Pub. No.: US 2010/0298590 A1
(43) Pub. Date: Nov. 25, 2010

(54) Silole-based monomers and polymers for organic light-emitting diode devices

(75) Inventors: Ali Hayek, Burnaby (CA); Xiaowei Zhan, Beijing (CN); Seth Marder, Atlanta, GA (US); Bernard Kippelen, Decatur, GA (US); Benoit Domerq, Waterloo (BE); Andreas Haldi, Dresden (DE)

Correspondence Address: Solvay;c/o B. Ortego - IAM-NAFTA, 3333 Richmond Avenue, Houston, TX, 77098-3099, US

(73) Assignee: GEORGIA TECH RESEARCH CORPORATION, Atlanta, GA (US)

(21) Appl. No.: 12/808,739

(22) PCT Filed: Dec. 19, 2008
(86) PCT No.: PCT/EP2008/068118

§ 371 Date: Aug. 16, 2010

Related U.S. Application Data
(60) Provisional application No. 61/015,650, filed on Dec. 20, 2007.

(51) Int. Cl. C07F 7/08

(52) U.S. Cl. 556/406

(57) ABSTRACT

This invention relates generally to organic electroluminescent norbornene-silole monomer, poly(norbornene) homopolymer, and poly(norbornene) copolymer compounds, containing functionalized aryl and alkyl silole side chains having good host characteristics and solution processability, and to an electron transporting and/or hole blocking layers, and light-emitting layers, organic electronic devices and compositions of matter, which include these compounds.

This utility patent application claims the priority of U.S. provisional patent application Ser. No. 61/015,650 filed 20 Dec. 2007, which is hereby incorporated herein by reference in it's entirety for all purposes.

### STATEMENT REGARDING FEDERALLY SPONSORED RESEARCH OR DEVELOPMENT

This invention was made with government support under a grant from the Office of Naval Research, Grant No. 68A-1060806. The U.S. Government has certain rights in this invention.

### TECHNICAL FIELD

This invention relates generally to norbornene monomer, poly(norbornene) homopolymer and poly(norbornene) copolymer compounds, containing a functionalized silole side chain, to an electron transporting and/or hole blocking layers, and light-emitting layers, organic electronic devices, organic electronic devices, and compositions of matter which include these compounds.

### BACKGROUND OF THE INVENTION

Siloles or silacyclopentadienes possess a unique sigma-pi(σ*-π*) conjugation that significantly lowers their lowest unoccupied molecular orbital energy levels (LUMO) and increases their electron affinities. In Luo, J. et al., Chem. Commun. 1740 (2001), siloles were shown to have intriguing aggregation-induced emissions in that they were almost nonluminescent in solution, but highly emissive in the solid state. The photoluminescence quantum yields of the aggregates of siloles can differ from that of their molecularly dissolved species by two orders of magnitude. Siloles also show cooling-enhanced emission, due to the fact that the photoluminescence of a silole solution increases with a decrease in the temperature. Additionally, the σ*-π* conjugation reduces the band gap as compared to cyclopentadiene, which makes siloles fluorescent materials.

Because of their high electron affinities and excimer-free aggregation-induced emissions attributes, siloles have been used as electron-transporting and light-emitting layers in the fabrications of highly efficient electroluminescence devices. There have been great efforts to incorporate siloles into polymers because polymers possess processing advantage over their small-molecule counterparts. Such efforts have included the use of silolyl polymers, such as poly(2,5-silole), poly(1,1-silole), silole-thiophene copolymers, silole-fluorene copolymers, silole-carbazole copolymers, poly(dithienosilole), silole-acetylene copolymers, silole-silane copolymers, silole side-chain polymers, hyperbranched polysiloles, and silole-cored dendrimers. In Chen J., Kwok H. S., Tang B. Z., Journal of Polymer Science: Part A: Polymer Chemistry, 2006, 44, 2487, a silole was synthesized and evaluated for there light emission properties. Prior to the Chen publication, silole containing polymers and copolymers were utilized in device applications, such as light-emitting diodes, photovoltaic cells, and field-effect transistors. Yamaguchi, S., et al, J. Chem. Soc. Dalton Trans., 1998, 3693; Luo, J., et al., Chem. Commun., 2001, 1740, and Chen, J., et al., Chem. Mater., 2003, 15, 1535.

Notwithstanding the efforts that have been made in the synthesis of silole-based polymers, there is currently a need for complex polymer architectures that can be used as host materials in the fabrication of Organic Light-Emitting Diode (OLED) devices, and that permit thin film deposition in OLED devices by solution processing. We have synthesized novel complex polymer architectures that are compatible with most functional groups and have the possibility to be living, a necessary prerequisite for block copolymers.

### SUMMARY OF THE INVENTION

An object of the present invention is to provide a novel organic electroluminescent norbornene monomers, poly(norbornene), or poly(norbornene) copolymer compounds containing functionalized aryl and alkyl silole side chains, to an electron transporting and/or hole blocking layers, and light-emitting layers, organic electronic devices, and compositions of matter containing said compounds.

In accordance with the purpose(s) of the invention, as embodied and broadly described herein, this invention in one aspect, relates to a compound represented by the formula (I):

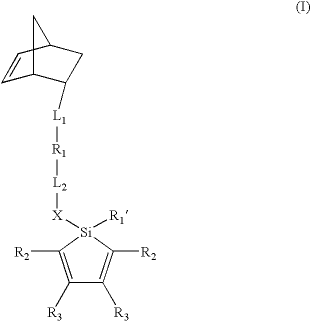

wherein:

X is arene diyl or alkane diyl, each of which are straight chain, branched chain or cyclic, having a carbon chain length of C₁₋₂₀;

L₁, and L₂ are independently absent, or represents

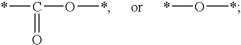

R₁ is absent or represents alkane diyl, alkene diyl, alkyne diyl, or arene diyl, each of which are straight chain, branched chain or cyclic, having a carbon chain length of C₁₋₂₀;

L₁-R₁-L₂ taken together is a linkage to the norbornene monomer, and is attached through the carbon or oxygen atom on the ester, or through the ether oxygen atom;

R₁′ is aryl; and

R₂ and R₃ are aryl.

In a second aspect, this invention relates to a compound represented by the formula (II):

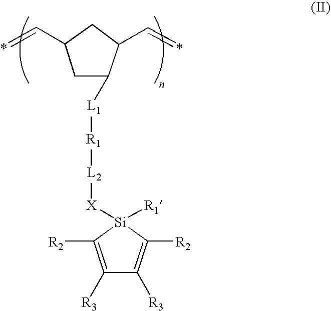

wherein:

X is arene diyl or alkane diyl, each are of which are straight chain, branched chain or cyclic, having a carbon chain length of C₁₋₂₀;

L₁, and L₂ are independently absent, or represents

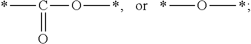

R₁ is absent or represents alkane diyl, alkene diyl, alkyne diyl, or arene diyl, each of which are straight chain, branched chain or cyclic, having a carbon chain length of C₁₋₂₀;

L₁-R₁-L₂ taken together is a linkage to the norbornene polymer, and is attached through the carbon or oxygen atom on the ester, or through the ether oxygen atom;

R₁′ is aryl;

R₂ and R₃ are aryl; and

n is an integer of from about 1 to about 2,000.

In a third aspect, the invention relates to electron transporting and/or hole blocking layers, and light-emitting layers comprising formula (I) or (II).

In a fourth aspect, the invention relates to a composition of matter for electron transporting and/or hole blocking layers, and light-emitting layers comprised of a compound of formulas (I) or (II) in combination with a phosphorescent dopant.

In a fifth aspect, the invention relates to a composition of matter containing the compound selected from the group consisting of:

a) compound 5;

b) compound 6;

c) compound 8;

d) compound AH-I-172

e) compound XZ-III-43; and

mixtures thereof.

In yet another aspect, this invention relates to organic electronic devices containing a silole material comprising the compound in formula (I), or (II), and blends thereof.

Preferably, the organic electroluminescence device emits red light, yellow light, green light, blue light, white light, or light with a broad band containing multiple color peaks. The norbornene compounds of the present invention can also be doped with other polymers to obtain white organic light-emitting diodes.

### BRIEF DESCRIPTION OF THE DRAWINGS

FIG. 1 shows the chemical structures of XZ-I-149A (reference compound), and XZ-II-87 and XZ-III-43, two novel norbornene compounds containing aryl silole side chains.

FIG. 2 is an UV absorption spectra of XZ-I-149A, XZ-II-87 and XZ-III-43 in chloroform.

FIG. 3 is an Emission spectra of XZ-I-149A, XZ-II-87 and XZ-III-43 in chloroform.

FIG. 4 is a PL spectra of XZ-II-87, XZ-III-43 and XZ-149A in film.

FIG. 5 is a Cyclic voltammogram of XZ-I-149A.

FIG. 6 is a Cyclic voltammogram of XZ-II-87.

FIG. 7 shows TGA curves of XZ-I-149A, XZ-II-87 and XZ-III-43.

FIG. 8 is a graph of DSC curves of XZ-I-149A.

FIG. 9 is a graph of DSC curves of XZ-III-43.

FIG. 10 is a diagram of device configuration of Example 3.

FIG. 11 is the maximum luminance and external quantum efficiency (EQE) as a function of voltage for the OLED devices of Example 3.

FIG. 12 is a graph of a time of flight signal of Example 4

FIG. 13 is a diagram of device configuration of Example 5.

FIG. 14 is the electroluminescence spectrum of OLED devices of Example 5.

FIG. 15 is the current density-Voltage (J-V) characteristics for OLED devices of Example 5.

FIG. 16 is the maximum luminance and external quantum efficiency (EQE) as a function of voltage for the OLED devices of Example 5.

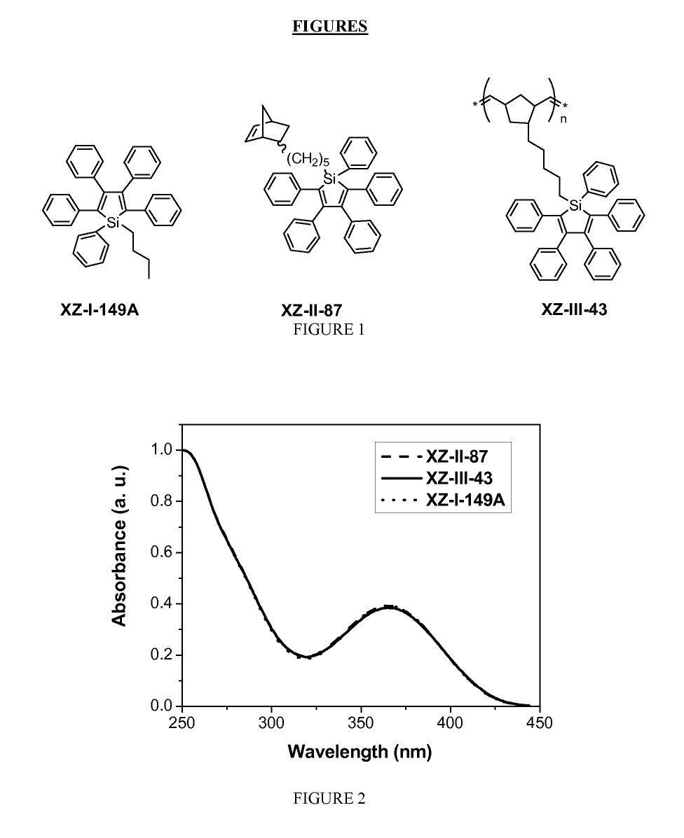

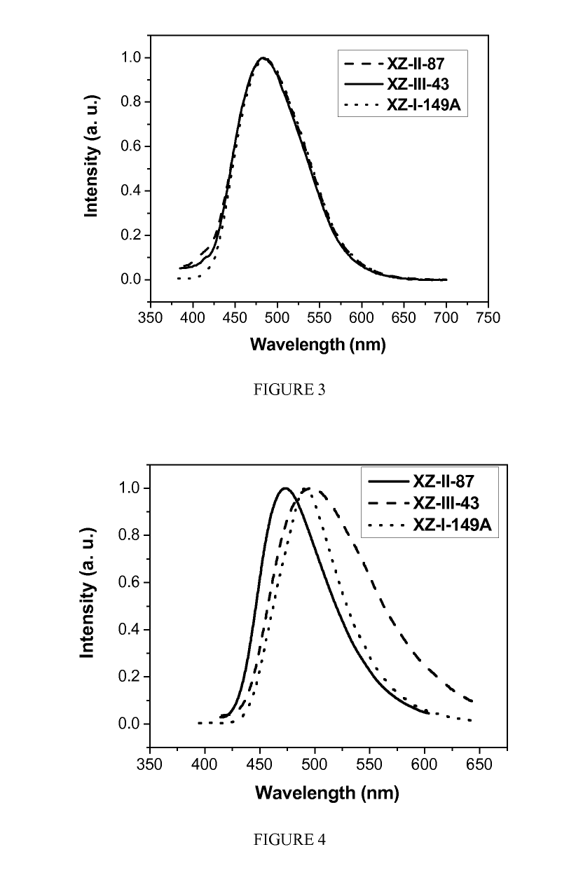

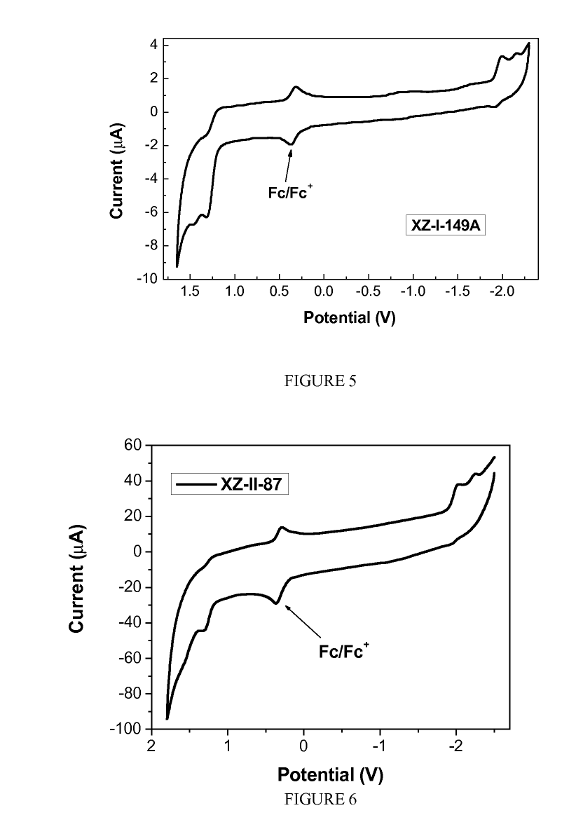

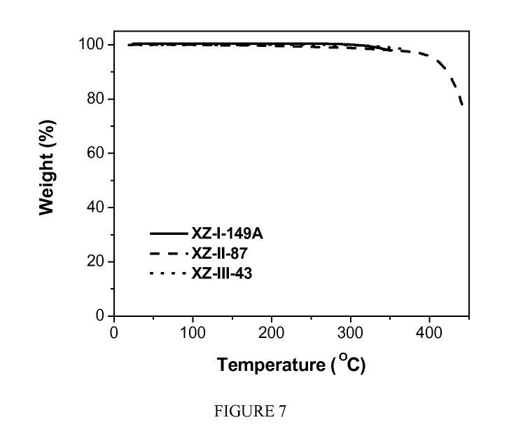

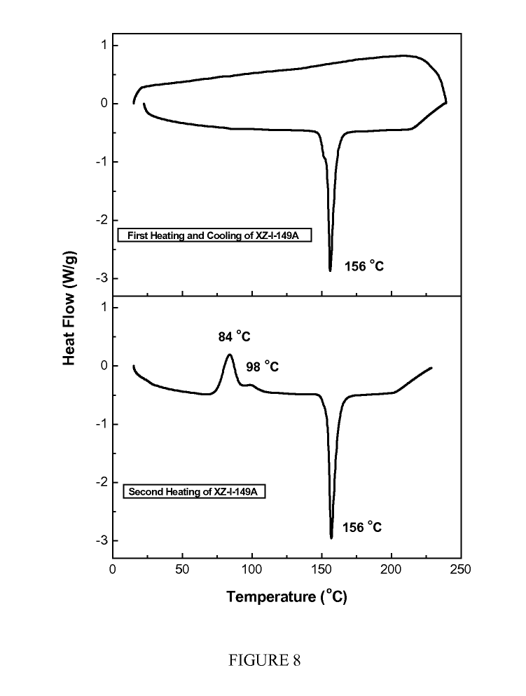

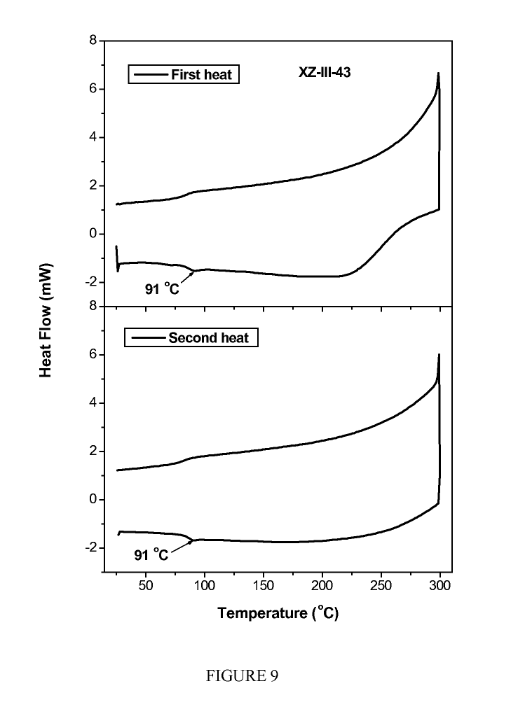

### DETAILED DESCRIPTION OF THE INVENTION

The present invention may be understood more easily by reference to the following detailed description of preferred embodiments of the invention and the examples included therein.

Before the present compounds, compositions, articles, devices, and or methods are disclosed and described, it is to be understood that the terminology used herein is for the purpose of describing particular embodiments only and is not intended to be limiting.

It must be noted that as used in the specification and the appended claims, the singular forms “a” “an” and “the” include plural referents unless the context clearly dictates otherwise. Thus, for example, reference to “a cyclic compound” includes mixtures of aromatic compounds.

In the specification and claims which follow, reference will be made to a number of terms which shall be defined to have the following meanings:

Ranges are often expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment.

The term “halogen” and “halo” refer to bromine, chlorine, fluorine and iodine.

The term “alkoxy” refers to a straight, branched or cyclic C₁₋₂₀ alkyl-O, with the alkyl group optionally substituted as described herein.

The terms “alkanediyl” or “alkane diyl” refer s to a straight chain, branched chain or cyclic alpha, omega-alkanediyl having a carbon chain length of from 1 to 20 carbon atoms, such as methane diyl, ethane diyl, propane diyl and the like.

The terms “alkenediyl” or “alkene diyl” refers to a straight chain, branched chain or cyclic alpha, omega-alkenediyl having a carbon chain length of from 1 to 20 carbon atoms, such as ethene diyl, propene diyl, butane diyl and the like.

The terms “alkynediyl” or “alkyne diyl” refers to a straight chain, branched chain or cyclic alpha, omega-alkynediyl having a carbon chain length of from 1 to 20 carbon atoms, such as ethyne diyl, propyne diyl, butyne diyl and the like.

The term “arene diyl” refers to an aromatic or heteroaromatic aryl group where two hydrogen atoms are removed allowing for a group to be substituted at the position where the two hydrogen atoms were removed, and having a chain length from 1 to 20 carbon atoms. The term “arene diyl” covers the same aromatic and heteroaromatic groups described above under the definition of aryl, but in which there are two points of attachment, rather than one.

The term “alkyl” refers to a branched or straight chain, or cyclic hydrocarbon group, having a carbon chain length of from 1 to 20 carbon atoms, such as methyl, ethyl, propyl, n-propyl, isopropyl, butyl, n-butyl, isobutyl, t-butyl, octyl, decyl, decyl, tetradecyl, hexadecyl, eicosyl, tetracosyl, cyclopentyl, cyclohexyl and the like. When substituted, alkyl groups may be substituted with at least one member selected from the group consisting of CN, NO₂, S, NH, OH, COO—, and halogen at any available point of attachment. When the alkyl group is said to be substituted with an alkyl, this is used interchangeably with “branched” alkyl group.

The term “alkenyl” refers to a hydrocarbon radical straight, branched or cyclic containing 1 to 20 carbon atoms and at least one carbon to carbon double bond. A more preferred alkenyl is C₃₋₁₀ alkenyl. Suitable alkenyl groups include, propenyl, butenyl and cyclohexenyl.

The term “alkynyl” refers to a hydrocarbon radical, straight, b ranched or cyclic containing from 1 to 20 carbon atoms and at least one carbon to carbon triple bond. A more preferred alkenyl is C₃₋₁₀ Preferred alkynyl groups include propynyl and butynyl.

The term “aryl” refers to aromatic rings used as substitutents, e.g. phenyl, substituted phenyl, and the like as well as rings which are fused, e.g. naphthyl, phenanthrenyl, and the like. An aryl group thus contains at least one ring having at least 6 atoms. Substituents on the aryl group may be present on any posit ion, i.e., ortho, meta, or para positions or fused to the aromatic ring. More particularly, aryl groups may be substituted or unsubstituted with an aromatic or heteroaromatic group, and the aromatic or heteroaromatic group may be substituted with a substituent independently selected from the group consisting of a different aryl group, alkyl groups, halogens, fluoroalkyl groups; alkoxy groups, and amino groups. Preferred substituted aryl aryl groups include phenyl, naphthyl and the like. The term “cyclic” can refer either to an aryl group or to a cyclic alkyl group such as a cyclohexyl substituent.

The term “heteroaryl” refer to a conjugated monocyclic aromatic hydrocarbon group having 5 or 6 ring atoms, a conjugated bicyclic aromatic group having 8 to 10 atoms, or a conjugated polycyclic aromatic group having at least 12 atoms, containing at least one heteroatom, O, S, or N, in which a C or N atom is the point of attachment, and in which 1 or 2 additional carbon atoms is optionally replaced by a heteroatom selected from O, or S, and in which from 1 to 3 additional carbon atoms are optionally replaced by nitrogen heteroatoms, said heteroaryl group being optionally substituted as described herein. Examples of this type are pyrrole, oxazole, thiazole and oxazine. Additional nitrogen atoms may be present together with the first nitrogen and oxygen or sulfur, giving, e.g. thiadiazole. Suitable heteroaryl compounds are carbazole, purine, indole, purine, pyridine, pyrimidine, pyrrole, imidazole, thiazole, oxazole, furan, thiophene, triazole, pyrazole, isoxazole, isothiazole, pyrazine, pyridazine, and triazine. A preferred substituent on the heterocyclic or heteroaryl is a carbazole substituted with alkyl groups such as t-butyl at the 3- and 6-position on the carbazole. The term “heterocyclic” can refer to both the heteroaryl species defined above, or to saturated heterocyclic groups.

The subscript “n” refers to the number of repeat units in the polymer. With respect to the polymers in this invention, “n” is from about 1 to about 2,000 repeat units. More preferably, “n” is from about 700 to about 1,500 repeat units. Most preferably, “n” is from about 20 to about 500 repeat units.

The asterisk (*) used herein is intended to denote the point of attachment on the chemical structure.

The term “Alq₃” is meant to describe tris(8-hydroquinolato)aluminum.

The term “Poly-TPD-F” is a copolymer of hole transporting monomers and crosslinking monomers and are represented by the following structure:

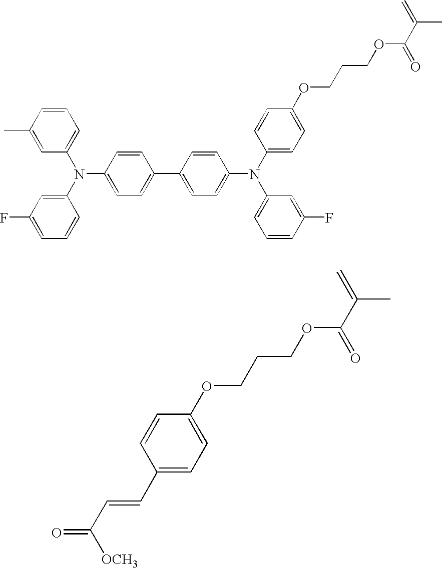

The terms “Poly-TPD-MeO” or “PolyTPD-MeO₂” are copolymers of hole transporting monomers and crosslinking monomers and are represented by the following structure:

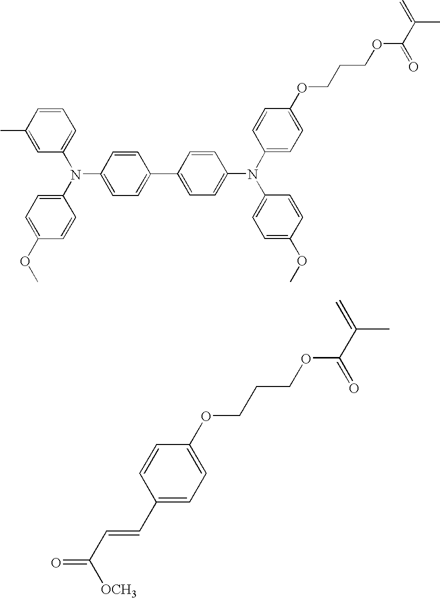

A device of electronic applications, includes but is not limited to, active electronic components, passive electronic components, electroluminescent (EL) devices (e.g., organic light-emitting devices (OLEDs)), photovoltaic cells, light-emitting diodes, field-effect transistors, phototransistors, radio-frequency ID tags, semiconductor devices, photoconductive diodes, metal-semiconductor junctions (e.g., Schottky barrier diodes), p-n junction diodes, p-n-p-n switching devices, photodetectors, optical sensors, phototransducers, bipolar junction transistors (BJTs), heterojunction bipolar transistors, switching transistor s, charge-transfer devices, thin-film transistors, organic radiation detectors, infra-red emitters, tunable microcavities for variable output wavelength, telecommunications devices and applications, optical computing devices, optical memory devices, chemical detectors, combinations thereof, and the like.

In order to achieve a complex silole containing polymer architecture with suitable compatibility, we have synthesized novel norbornene-monomer and polymer systems containing aryl and alkyl silole chains. These novel norbornene-monomer and polymer systems containing aryl and alkyl silole chains can be readily polymerized using the Ring-Opening Metathesis Polymerization (ROMP) process, which is initiated by a ruthenium catalyst.

This novel invention also provides a wide variety of functionalized amorphous polymers that are suitable for grafting reactions of other silole-based groups and for incorporating high loadings of phosphors while minimizing interaction between phosphors.

Furthermore, this novel invention is also designed to provide a more stable silole than what is presently know in the field of endeavor.

This invention is directed to covalently grafted metal complexes onto poly(norbornene)s as materials for use in organic light-emitting diodes (OLED). Poly(norbornene)s can be polymerized via ring-opening metathesis polymerization (ROMP), a living polymerization method resulting in polymers with controlled molecular weights, low polydispersities, and also allows for the formation of block co-polymers. See, for example, Fürstner, A. Angew. Chem., Int. Ed. 2000, 39, 3013; T. M. Trnka, T. M.; Grubbs, R. H. Acc. Chem. Res. 2001, 34, 18; Olefin Metathesis and Metathesis Polymerization, 2nd Ed.; Ivin, J., Mol, I. C., Eds.; Academic: New York, 1996; and Handbook of Metathesis, Vol. 3—Application in Polymer Synthesis; Grubbs, R. H., Ed.; Wiley-VCH: Weinheim, 2003, each of which is respectively incorporated herein by reference in its entirety. Furthermore, ruthenium-based ROMP initiators are highly functional-group tolerant, allowing for the polymerization of norbornene monomers containing fluorescent and phosphorescent metal complexes.

Charge-transport molecular and polymeric materials are semiconducting materials in which charges can migrate under the influence of an electric field. These charges may be present due to electrical doping with oxidizing or reducing agents, so that some fraction of the transport molecules or polymer repeat units is present as radical cations or anions. More usually, charges are introduced by injection from another material under the influence of an electric field. Charge-transport materials may be classified into hole- and electron-transport materials. In a hole-transport material, electrons are removed, either by electrical doping or injection, from a filled manifold of orbitals to give positively charged molecules or polymer repeat units. Transport takes place by electron-transfer between a molecule or polymer repeat unit and the corresponding radical cation; this can be regarded as movement of a positive charge (hole) in the opposite direction to this electronic motion. In an electron-transport material, extra electrons are added, either by electrical doping or injection; here the transport process includes electron-transfer from the radical anion of a molecule or polymer repeat unit to the corresponding neutral species.

The monomeric norbornene compounds and polymers thereof of the present invention can be chemically doped with phosphorescent metal complexes as guests or co-polymerized with metal phosphorescent complexes. The phosphorescent dopant is preferably a metal complex comprising at least one metal selected from the group consisting of Ir, Rd, Pd, Pt, Os and Re, and the like. More specific examples of the phosphorescent dopants include but are not limited to metal complexes such as tris(2-phenylpyridinato-N,C²)ruthenium, bis(2-phenylpyridinato-N,C²)palladium, bis(2-phenylpyridinato-N,C²)platinum, tris(2-phenylpyridinato-N,C²)osmium, tris(2-phenylpyridinato-N,C²)rhenium, octaethyl platinum porphyrin, octaphenyl platinum porphyrin, octaethyl palladium porphyrin, octaphenyl palladium porphyrin, iridium(III)bis[(4,6-difluorophenyl)-pyridinato-N,C^{2′}]picolinate (Firpic), tris-(2-phenylpyridinato-N,C²)iridium Ir(ppy)₃), green material bis-(2-phenylpyridinato-N,C²)iridium(acetylaacetonate)(Ir(ppy)₂ (acac), and red material 2,3,7,8,12,13,17,18-octaethyl-21H,23H-porphine platinum(II) (PtOEP) as well as other known to those skilled in the art of OLEDs and metallo-organic chemistry.

A plurality of layers of charge-transport material can be produced to form a charge-transport layer that can have a thickness of about 0.01 to 1000 μm, 0.05 to 100 μm, 0.05 to 10 μm. The length and width of the charge-transport layer can vary depending on the application, but in general, the length can be about 0.01 μm to 1000 cm, and the width can be about 0.01 μm to 1000 cm.

It should also be noted that the charge-transport materials could be used as mixtures with other electro n transport materials including those described herein, as well as others. Likewise the charge-transport materials could be used in combination with other hole transport materials, sensitizers, emitters, chromophores, and the like, to add other functionality to devices.

The polymerization and cross-linking of the charge-transport material molecules can be performed using methods understood by those skilled in the art. In general, polymerization may take place by exposure to heat or actinic radiation in the presence of an initiator. In general, cross-linking may occur due to internal reactions and/or by the addition of a cross-linking additive. Additional details regarding preparation of the charge-transport materials are described in Example 1.

Actinic radiation means irradiation with radiation (e.g., UV light, IR light or visible light, irradiation with X-rays or gamma rays or irradiation with high-energy particles, such as ions or electrons). In an embodiment, a polymerization initiator can be used that decomposes when heated to produce free radicals or ions that start the polymerization. In another embodiment, the polymerization can be carried out in the presence of an initiator absorbing at the wavelength of the actinic radiation. For example, when polymerizing using UV light, a UV initiator can be used that decomposes under UV irradiation to produce free radicals or ions which start the polymerization reaction.

The UV initiator can include chemicals such as, but not limited to, a free radical initiator, a cationic initiator, or combinations thereof. The free-radical initiator includes compounds that produce a free radical on exposure to UV radiation. The free-radical is capable of initiating a polymerization reaction among the monomers and/or oligomers present.

Examples of free-radical initiators include, but are not limited to, benzophenones (e.g., benzophenone, methyl benzophenone, Michler's ketone, and xanthones), acylphosphine oxide type free radical initiators (e.g., 2,4,6-trimethylbenzoyldiphenyl phosphine oxide (TMPO), 2,4,6-trimethylbenzoylethoxyphenyl phosphine oxide (TEPO), and bisacylphosphine oxides (BAPO's)), azo compounds (e.g., AIBN), benzoins, and benzoin alkyl ethers (e.g., benzoin, benzoin methyl ether and benzoin isopropyl ether).

In addition, the free radical photoinitiator can include, but is not limited to: acyloin; a derivative of acyloin, such as benzoin ethyl ether, benzoin isobutyl ether, desyl bromide, and α-methylbenzoin; a diketone, such as benzil and diacetyl; an organic sulfide, such as diphenyl monosulfide, diphenyl disulfide, desyl phenyl sulfide, and tetramethylthiuram monosulfide; a thioxanthone; an S-acyl dithiocarbamate, such as S-benzoyl-N,N-dimethyldithiocarbamate and S-(p-chlorobenzoyl)-N,N-dimethyldithiocarbamate; a phenone, such as acetophenone, α-α-α-tribromoacetophenone, o-nitro-α-α-α-tribromoacetophenone, benzophenone, and p,p′-tetramethyldiaminobenzophenone; a quinone; a triazole; a sulfonyl halide, such as p-toluenesulfonyl chloride; a phosphorus-containing photoinitiator, such as an acylphosphine oxide; an acrylated amine; or mixtures thereof.

The free-radical initiator can be used alone or in combination with a co-initiator. Co-initiators are used with initiators that need a second molecule to produce a radical that is active in UV-systems. For example, benzophenone uses a second molecule, such as an amine, to produce a reactive radical. A preferred class of co-initiators are alkanolamines such as, but not limited to, triethylamine, methyldiethanolamine, and triethanolamine

Suitable cationic initiators include, but are not limited to, compounds that form aprotic acids or Brønsted acids upon exposure to UV light sufficient to initiate polymerization. The cationic initiator used may be a single compound, a mixture of two or more active compounds, or a combination of two or more different compounds (e.g., co-initiators).

The cationic photoinitiator can include, but is not limited to, onium salt, such as a sulfonium salt, an iodonium salt, or mixtures thereof. In addition, the cationic photoinitiatior can include, but is not limited to, an aryldiazonium salt, a bis-diaryliodonium salt, a diaryliodonium salt of sulfonic acid, a triarylsulfonium salt of sulfonic acid, a diaryliodonium salt of boric acid, a diaryliodonium salt of boronic acid, a triarylsulfonium salt of boric acid, a triarylsulfonium salt of boronic acid, or mixtures thereof. Examples of cationic photoinitiators include, but are not limited to, diaryliodonium hexafluoroantimonate, aryl sulfonium hexafluorophosphate, aryl sulfonium hexafluoroantimonate, bis(dodecyl phenyl)iodonium hexafluoroarsenate, tolyl-cumyliodonium tetrakis(pentafluorophenyl)borate, bis(dodecylphenyl)iodonium hexafluoroantimonate, dialkylphenyl iodonium hexafluoroantimonate, diaryliodonium salts of perfluoroalkylsulfonic acids (such as diaryliodonium salts of perfluorobutanesulfonic acid, perfluoroethanesulfonic acid, perfluorooctanesulfonic acid, and trifluoromethane sulfonic acid), diaryliodonium salts of aryl sulfonic acids (such as diaryliodonium salts of para-toluene sulfonic acid, dodecylbenzene sulfonic acid, benzene sulfonic acid, and 3-nitrobenzene sulfonic acid), triarylsulfonium salts of perfluoroalkylsulfonic acids (such as triarylsulfonium salts of perfluorobutanesulfonic acid, perfluoroethanesulfonic acid, perfluorooctanesulfonic acid, and trifluoromethane sulfonic acid), triarylsulfonium salts of aryl sulfonic acids (such as triarylsulfonium salts of para-toluene sulfonic acid, dodecylbenzene sulfonic acid, benzene sulfonic acid, and 3-nitrobenzene sulfonic acid), diaryliodonium salts of perhaloarylboronic acids, triarylsulfonium salts of perhaloarylboronic acid, or mixtures thereof.

The visible radiation initiator can include, but is not limited to, diketones (e.g., camphorquinone, 1,2-acenaphthylenedione, 1H-indole-2,3-dione, 5H-dibenzo[a,d]cycloheptene-10, and 11-dione), phenoxazine dyes (e.g., Resazurin, Resorufin), acylphosphine oxides, (e.g., diphenyl (2,4,6-trimethylbenzoyl)phosphine oxide), and the like.

### EXPERIMENTAL

The following examples are put forth so as to provide those of ordinary skill in the art with a complete disclosure and description of how the compounds, compositions, articles, devices and/or methods claimed herein are made and evaluated, and are intended to be purely exemplary of the invention are not intended to limit the scope of what the inventors regard as their invention. Efforts have been made to ensure accuracy with respect to numbers (e.g. amounts, temperature, etc.) but some errors and deviations should be accounted for. Unless indicated otherwise indicated, parts are parts by weight, temperature is in ° C. or is at ambient temperature and pressure is at or near atmospheric.

### Example 1

### Synthesis of AH-I-172

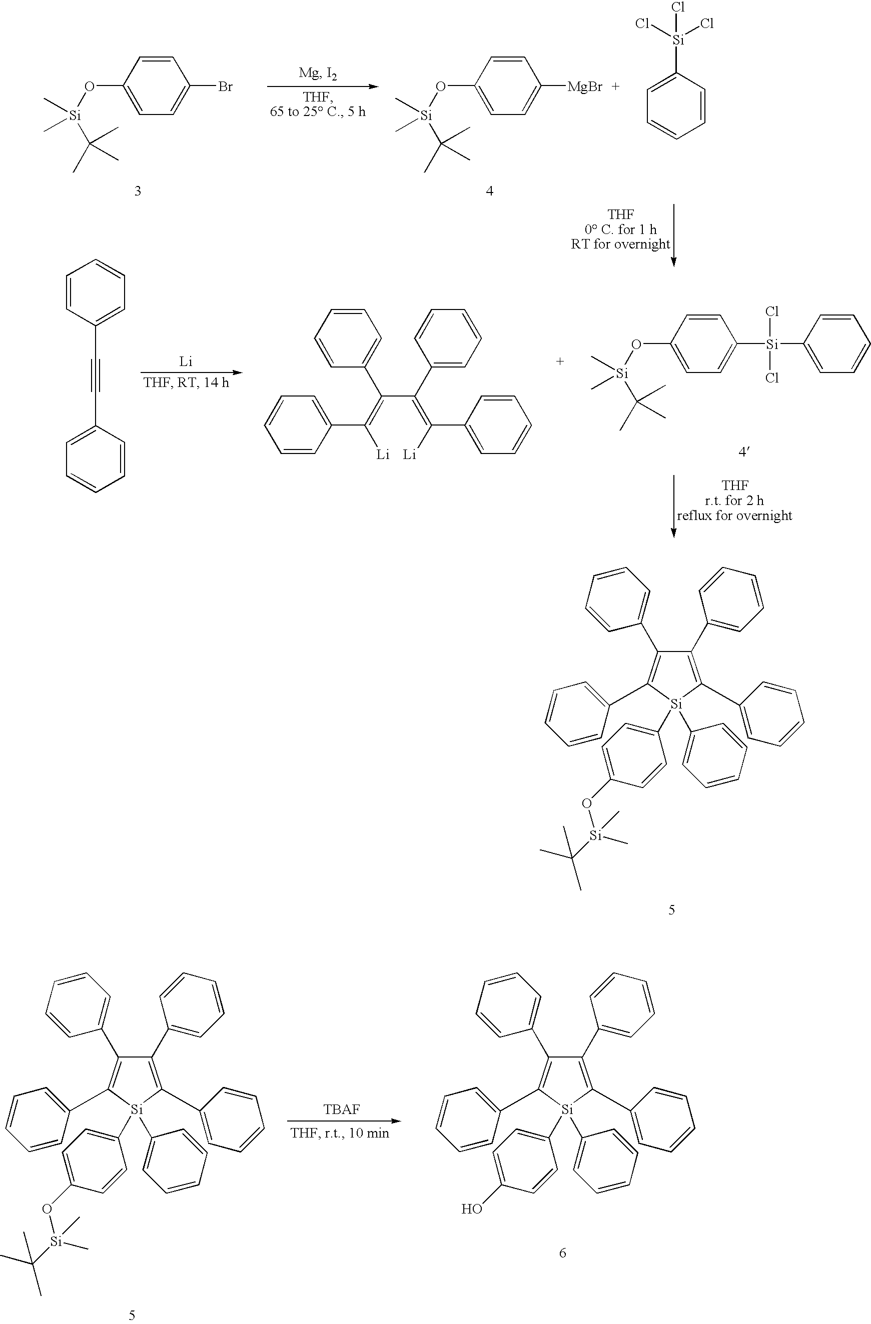

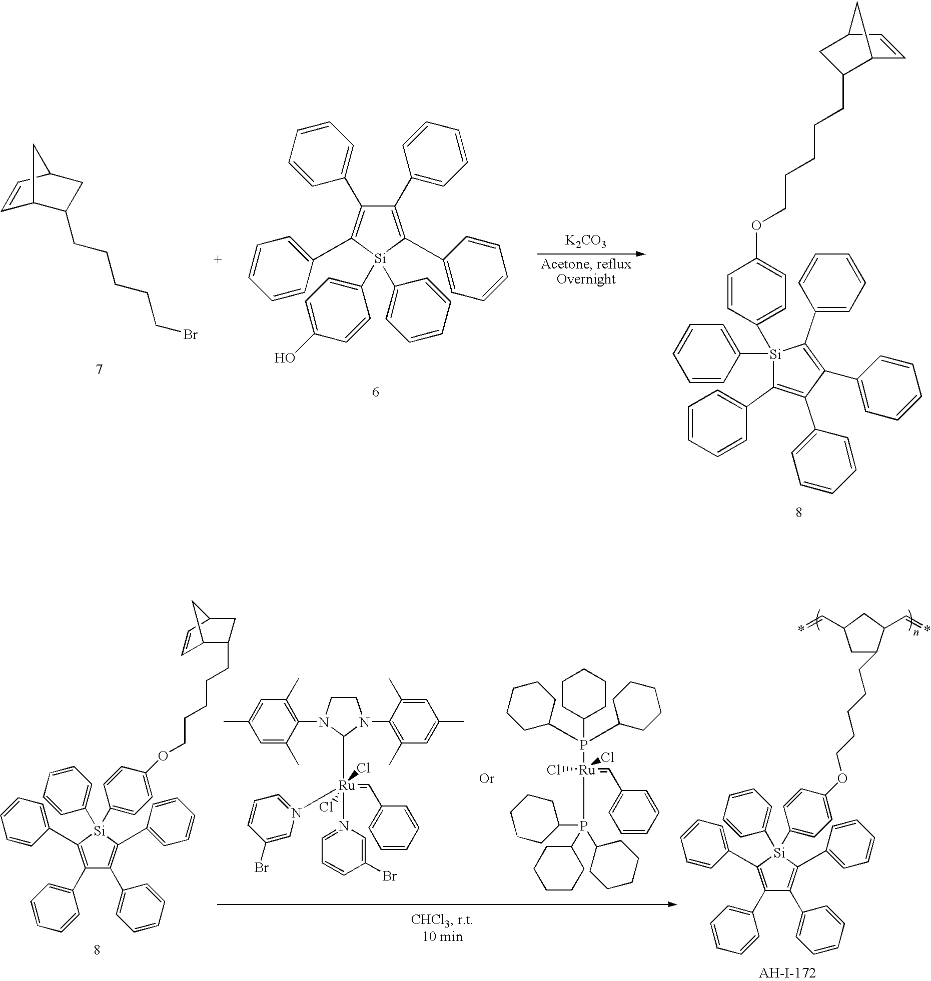

### Step 1: Synthesis of Bis Lithium Intermediate Compound

Consists of the action of the lithium on the triple bond of the acetylene group to form the bis-lithium intermediate compound. For the preparation of this intermediate, see Tang, et al., J. Mater. Chem., 2001, 11 2974-2978.

### Step 2

### A. Synthesis of 4-Bromo(tert-butyldimethylsilyl)-phenoxy (3)

To a solution of bromophenol or 4-bromo-4′-hydroxybiphenyl (0.20 mol, 34.6 g) in DMF (240 mL) was added tert-butyl-dimethylsilyl chloride (TBDMS-Cl, 30.2 g, 0.20 mol) at 25° C. Imidazole (34.0 g, 0.40 mol) was carefully added to the solution, and stirring was continued for 3 hours at 25° C. The reaction mixture was poured into saturated aqueous NaHCO₃ (400 mL) and the aqueous phase was extracted with hexane (3×200 mL). The combined organic phase was washed with brine (3×100 mL) and H₂O (100 mL), dried over MgSO₄, and concentrated in vacuo to give silylated aryl bromide as a colorless oil. 49.6 g (86%).

¹H-NMR δ ppm (400 MHz, CDCl₃) 7.30 (d, J=12 Hz, 2H), 6.70 (d, J=12 Hz, 2H), 0.95 (s, 9H), 0.16 (s, 6H).

### B. Grignard derivative of the protected 4-Bromophenol (4)

The silylated aryl bromide (3) (3.62 g, 12.6 mmol) was added to magnesium (306 mg, 12.6 mmol, 1.0 equiv) in 30 mL of dry THF under nitrogen in the presence of a catalytic amount of iodine at 60° C. After the red brown color of the mixture disappeared, the reaction mixture was cooled to 25° C. and stirred until the magnesium was almost consumed (2-5 hours).

### Step 3. Dichloro[tert-butyl(dimethyl)silylphenoxy]phenylsilane (4′)

A solution of compound 4 (18 g of 3, 62 mmol and 1.52 g of magnesium turnings, 62 mmol) in THF (30 mL) was added dropwise to a solution of phenyltrichlorosilane (13.12 g, 62 mmol) in THF (40 mL) at 0° C. The reaction mixture was allowed to warm to room temperature and stirred overnight under nitrogen. The product was used directly in-situ for further reaction.

### Step 4: Synthesis of 1-Phenyl-1-[4-(tert-butyldimethylsilyl)-phenoxy]-2,3,4,5-tetraphenylsilole (5)

The functionalized silane derivative (4′) obtained in step 3 was reacted with the bis-lithium intermediate compound above to provide compound (5). Diphenylacetylene (124.00 mmol, 22.10 g) and clean lithium shavings (124.00 mmol, 868 mg) were charged in a 100 mL three-necked round bottom flask, and were deoxygenated with nitrogen for 30 minutes. 30 mL of dry THF were then added. The reaction mixture was stirred at room temperature for 14 hours under nitrogen atmosphere. The deep green mixture was diluted with 50 mL of dry THF, and then transferred via cannula to an addition funnel of the reaction setup containing the prepared new silane derivative (4′). The addition funnel content was added dropwise to the silicon chloride solution over a period of 0.5 h at room temperature. The brown mixture was stirred at the same temperature for two hours, and then was refluxed overnight. The resulting yellow-green solution was washed with water; the organic layer was extracted with ether, and dried over MgSO₄. The solvent was removed under vacuum and the residue was purified by column chromatography over silica gel using hexanes/dichloromethane (8/1 in volume) as eluent, to afford 5 as yellow solid: 9.7 g (25%). ¹H-NMR δ ppm (400 MHz, CDCl₃) 7.66-6.70 (m, 29H), 0.99 (s, 6H), 0.97 (s, 3H), 0.21 (s, 6H).

### Step 5: 1-Phenyl-1-(p-phenol)-2,3,4,5-tetraphenylsilole (6)

A solution of protected silole (3.47 g, 5.19 mmol) in THF (40 mL) was prepared in a round bottom flask. 2.11 mL of tetrabutylammonium fluoride (7.28 mmol, TBAF, 1 M in THF) were added dropwise and the reaction mixture was stirred at room temperature. The reaction was monitored by TLC, while it was complete after 10 minutes. The THF was removed on a rotor evaporator, and the compound was purified by chromatography on silica eluting with a mixture of hexanes/dichloromethane 8:2 (v/v) then pure dichloromethane, to yield 2.60 g of the desired compound as yellow solid (90%). ¹H-NMR δ ppm (400 MHz, CDCl₃) 7.64 (m, 2H), 7.52 (m, 2H), 7.26-7.48 (m, 4H), 7.04-6.92 (m, 11H), 6.90-6.78 (m, 10H), 4.89 (s, 1H). MS (FAB) 554.20 calculated for C₄₀H₃₀OSi 554.21.

### Step 6: 5-(5-Bromopentyl)bicyclo[2.2.1]hept-2-ene (7)

Magnesium turnings (2.42 g, 0.099 mol) in 80 mL of dry THF were placed in a three-neck flask equipped with a condenser, nitrogen inlet, and addition funnel containing norbornylmethylene bromide (16.22 g, 0.086 mol). The norbornene was slowly added to the magnesium over an hour period, and the solution was cooled and transferred via a cannula into an addition funnel that was attached to a Schlenk flask charged with Li₂CuCl₄ (0.1 M in THF, 10 mL) and 1,4-dibromobutane (22.95 g, 0.106 mol). The reaction mixture was cooled to approximately −20° C., and the Grignard solution was added slowly over 2 hours. The reaction mixture was slowly warmed to room temperature overnight. Diethyl ether (100 mL) was added to the solution, and it was washed with saturated NH₄Cl solution. The aqueous layer was extracted with ether; the organic layers were combined and then washed with brine. The volatile components were removed on the rotor evaporator, and the residue was distilled under reduced pressure; yielding a yellowish oil 10 g (44%).

¹H-NMR δ ppm (400 MHz, CDCl₃) 6.10 (1H, m, HCCH_{endo}), 6.08 (1H, m, HCCHₑₓₒ), 6.02 (1H, m, HCCHₑₓₒ), 5.91 (1H, m, HCCH_{endo}), 3.37 (2H, m, (CH₂)₅CH₂Br), 2.72 (2H, m, CHCHCHCH_{2norb}), 2.0-1.76 (5H, m), 1.5-0.9 (6H, m), 0.49 (1H, m, (CH₂)₅CHCHH).

### Step 7: 1-(4-(5-(bicyclo[2.2.1]hept-5-en-2-yl)pentyloxy)phenyl)-1,2,3,4,5-pentaphenyl-1H-silole (8)

In a two-neck round bottom flask equipped with condenser and septum, 1.00 g of 6 (1.80 mmol), 1.25 g of 7 (4.50 mmol) and 40 mL of acetone were charged. 1.39 g of K₂CO₃ was added in small fraction, and the reaction mixture was refluxed overnight. The reaction mixture was cooled down to room temperature, and the acetone was removed on rotor evaporator to afford a yellow solid. The product was purified by column chromatography on silica gel using a mixture of hexanes/dichloromethane 5/5 (v/v) as eluant; yield 723 mg of the desired compound as yellow solid (56%). ¹H-NMR δ ppm (400 MHz, CDCl₃) 7.63 (dd, 2H), 7.55 (d, 2H), 7.42-7.30 (m, 4H), 7.80-6.92 (m, 11H), 6.78-6.91 (m, 10H), 6.10-6.07 (m, 1H_{exo, endo}), 6.20-5.80 (m, 1Hₑₓₒ)5.95-5.80 (m, 1H_{endo}), 3.93 (t, 2H), 3.38 (t, 1H), 2.72 (bs, 3H), 2.40-1.62 (m, 4H), 1.48-0.98 (m, 4H), 0.92-0.78 (m, 1H), 0.48-0.43 (m, 1H). MS (EI) 716.50 calculated for C₅₂H₄₈OSi 716.35.

### Step 8: Polymer-I (AH-I-172)

Third generation Grubbs' catalyst. To a 25 mL two-neck flask 730 mg of 8 (1.018 mmol), was added, and deoxygenated with nitrogen for 30 minutes. A solution of 9.01 mg of third generation Grubbs' catalyst (0.010 mmol) in 5 mL of THF was prepared in purged vial, and syringed into the reaction mixture, which was stirred at room temperature for 15 minutes. To quench the polymerization, couple drops of ethylvinyl ether were added and the mixture was stirred for 20 minutes. The yellow solution was dropped into 75 mL of ethanol, the precipitated polymer was filtered, then dissolved in CH₂Cl₂ and precipitated in ethanol four times, then filtered and dried to yield 500 mg of a yellow solid (68%). ¹H-NMR δ ppm (400 MHz, CDCl₃) 7.63 (bd, 2H), 7.53 (bd, 2H), 7.42-7.25 (m, 4H), 7.3-6.5 (m, 21H), 5.5-5.4 (m, 5H), 4.05-3.7 (m, 4H), 3.5-0.8 (m, 10H). GPC results: Mn=13000, Mw=30000, DP=18, PDI=2.33. Anal. Calcd for C₅₂H₄₈OSi: C, 87.10; H, 6.75. Found: C, 86.48; H, 7.05.

### Example 2

### Scheme 1

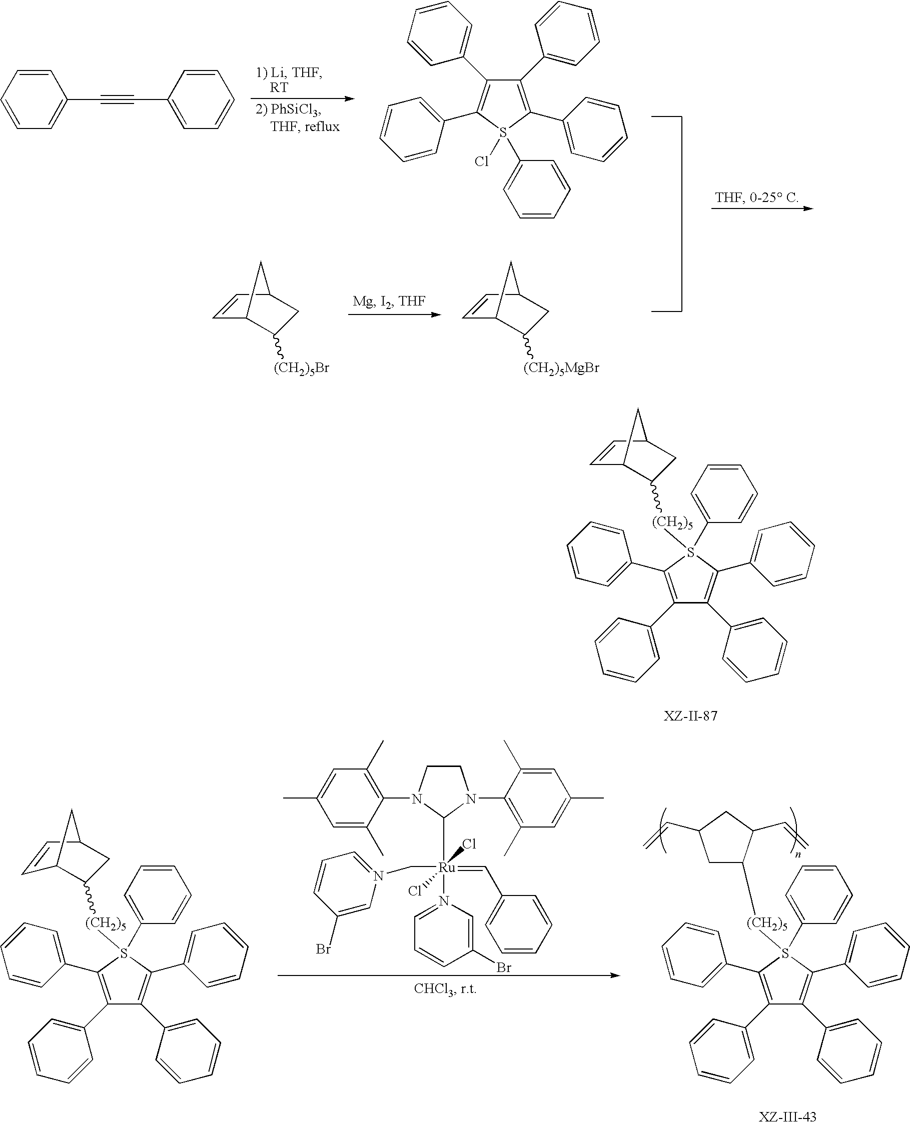

### Step 1: Synthesis of XZ-II-87

### A. Preparation of XZ-III-17

Diphenylacetylene (33.4 mmol, 6.0 g) and clean lithium shavings (28 mmol, 196 mg) were put in a 100 mL three-necked round bottom flask, and were deoxygenated with nitrogen for 30 minutes. 30 mL of dry THF was then added. The reaction mixture was stirred at room temperature for 14 hours under nitrogen atmosphere. The deep green mixture was diluted with 50 mL of dry THF, transferred to an addition funnel. Another 250 mL three-necked round bottom flask was deoxygenated with nitrogen for 30 minutes, and 20 mL dry THF and PhSiCl₃ (12.6 mmol, 2.66 g) were added. The resulting suspension was added dropwise to the silicon chloride solution over a period of 0.5 hours at room temperature. The brown mixture was stirred at the same temperature for 2 hours, and then was refluxed for 5 hours to give a dark yellow solution.

### B. Light gray mixture: Grignard reagent of 5-(5-Bromopentyl)bicyclo[2.2.1]hept-2-ene

To a 250 mL three-necked round bottom flask were added magnesium shavings (20 mmol, 480 mg), 5-norbornene-2-pentyl bromide JYC-II-055 (12.6 mmol, 3.06 g) and a little iodine, which were deoxygenated with nitrogen for 30 minutes. Then, 20 mL dry THF was added, and the mixture was stirred at 40° C. for 8 hours. The color of the mixture changed from light red to colorless and then to light gray.

### C. XZ-II-87

Both the dark yellow silole chloride solution and light gray Grignard reagent solution above were cooled to 0° C., and the latter was added dropwise to the former for 30 minutes. The deep greenish brown mixture was stirred for 1 hour at 0° C., was gradually warmed to room temperature, and stirred overnight. The resulting yellow-green solution was washed with water, the organic layer was extracted with ether, and dried over MgSO₄. The solvent was removed and the residue was purified by flash column chromatography over silica gel using hexane/dichloromethane=8/1 as eluent and recrystallization from methanol to afford pale yellow and strong blue fluorescent solids (2.0 g, 25.6%). XZ-II-87: 5 mmol, 1.0 g, 32.1%.

¹H NMR (300 MHz, CDCl₃): δ 7.64 (m, 2H), 7.34 (m, 3H), 7.01 (m, 12H), 6.85 (m, 8H), 6.08 (m, 1.3H), 5.87 (m, 0.7H), 2.72 (s, 2H), 1.93-1.76 (m, 2H), 1.53 (m, 2H), 1.42-1.16 (m, 8H), 1.00 (m, 2H), 0.46 (m, 1H). ¹³C NMR (75 MHz, CDCl₃): δ 155.98, 139.75, 139.48, 138.85, 136.70, 134.79, 133.01, 132.31, 129.85, 129.69, 128.90, 128.08, 127.68, 127.35, 126.18, 125.42, 49.57, 45.4 3, 42.56, 38.75, 34.67, 33.26, 32.50, 28.28, 23.336, 10.82. HRMS (EI), m/z 624.3182 (calcd for C₄₆H₄₄Si, 624.3212). Anal. Calcd for C₄₆H₄₄Si: C, 88.41; H, 7.10. Found: C, 88.28; H, 7.15.

### Step 2: XZ-III-43

To a 25 mL flask monomer XZ-II-87 (0.5 mmol, 312 mg), and a 3rd generation Grubbs' catalyst, 0.005 mmol, 4.42 mg) were added, and deoxygenated with nitrogen for 30 minutes. 10 mL of chloroform was added, and stirred at room temperature overnight. To quench the polymerization, a couple drops of ethyl vinyl ether was added. The yellow solution was dropped into 100 mL of ethanol, and a light yellow precipitate occurred. The light yellow solid was dissolved in 5 mL of chloroform and precipitated in 100 mL ethanol to give a pale yellow solid (301 mg, 96.5%).

¹H NMR (300 MHz, CDCl₃): δ 7.60 (m, 2H), 7.30 (m, 3H), 6.96-6.83 (m, 20H), 5.20 (s, br, 2H), 2.90-2.30 (m, br, 2H), 1.82 (m, br, 3H), 1.50-0.80 (m, br, 10H). ¹³C NMR (75 MHz, CDCl₃): δ155.92, 139.75, 139.43, 138.78, 134.73, 132.93, 129.81, 129.67, 128.84, 128.06, 127.68, 127.35, 126.16, 125.42, 45.44, 43.18, 42.47, 40.06, 37.10, 33.33, 31.72, 28.26, 23.42, 10.76. Anal. Calcd for (C₄₆H₄₄Si)ₙ: C, 88.41; H, 7.10. Found: C, 88.01; H, 7.12. GPC, polystyrene as standard, dichloromethane as eluent): weight-average molecular weight (Mw), 1.02×10⁶; molecular weight distribution (MWD), 2.96.

The performance of novel compounds XZ-II-87 and XZ-III-43, against reference XZ-I-149A, are shown below in Tables 1-5.

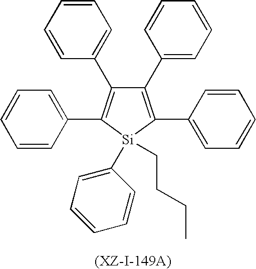

TABLE 1
UVA data of compounds in chloroform

| | λₘₐₓ (nm), | | |
|---|---|---|---|
| Compounds | ε (10⁴ mol⁻¹ L cm⁻¹) | | Band gap (eV) |
| XZ-I-149A (reference) | 251 (2.79) | 365(1.10) | 2.93 |
| XZ-II-87 (monomer) | 250 (2.26) | 365 (0.89) | 2.95 |
| XZ-III-43 (polymer) | 250 (2.55) | 365 (0.98) | 2.95 |

TABLE 2
UV data of compounds in films

| | λₘₐₓ (nm) | | Band gap (eV) | |
|---|---|---|---|---|
| Compounds | In solution | In film | In solution | In film |
| XZ-I-149A (reference) | 251, 365 | 252, 370 | 2.93 | 2.84 |
| XZ-II-87 (monomer) | 250, 365 | 251, 372 | 2.95 | 2.81 |
| XZ-III-43 (polymer) | 250, 365 | 252, 369 | 2.95 | 2.84 |

TABLE 3
PL data for compounds in films

| | λₘₐₓ (nm) | | fwhm (nm) | |
|---|---|---|---|---|
| Compounds | In solution | In solid | In solution | In solid |
| XZ-I-149A (reference) | 494 | 492 | 97 | 66 |
| XZ-II-87 (monomer) | 484 | 473 | 98 | 73 |
| XZ-III-43 (polymer) | 483 | 496 | 95 | 104 |

TABLE 4
CV data summarizes oxidation and reduction potentials,
and HOMO and LUMO energy levels of compounds

| | Eₒₓ | E_{red} | HOMO | LUMO | E_{g} |
|---|---|---|---|---|---|
| Compounds | (vs Fc/Fc⁺) V | (vs Fc/Fc⁺) V | (eV) | (eV) | (eV) |
| XZ-I-149A | 0.94 | −2.30 | −6.09 | −2.85 | 3.25 |
| (reference) | | | | | |
| XZ-II-87 | 1.00 | −2.37 | −6.15 | −2.78 | 3.36 |
| (monomer) | | | | | |
| XZ-III-43 | 1.02 | −2.37 | −6.18 | −2.78 | 3.40 |
| (polymer) | | | | | |

TABLE 5
A comparison of the thermal stability
of the compounds

| Compounds | T_{TGA} (° C.) | Tₘ (° C.) | T_{g} (° C.) |
|---|---|---|---|
| XZ-I-149A (reference) | 313 | 156 | — |
| XZ-II-87 (monomer) | 312 | 109 | — |
| XZ-III-43 (polymer) | 415 | — | 91 |

### Example 3

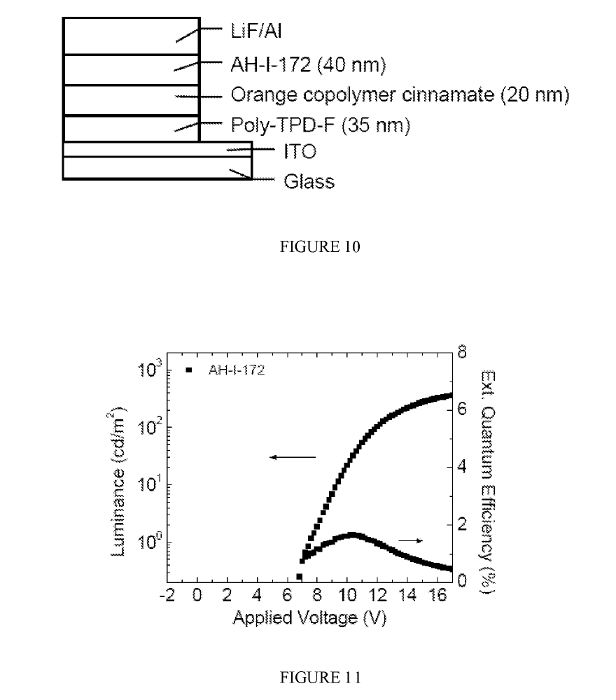

This example illustrates the formation of an OLED device using polysilole compound AH-I-172 (of Example 1) as an electron transport and/or hole blocking layer. The configuration of the device is ITO/Poly-TPD-F (35 nm)/orange copolymer cinnamate (20 nm)/polysilole (40 nm)/LiF/Al and is shown in FIG. 10. Orange copolymer cinnamate and Poly-TPD-F are shown below:

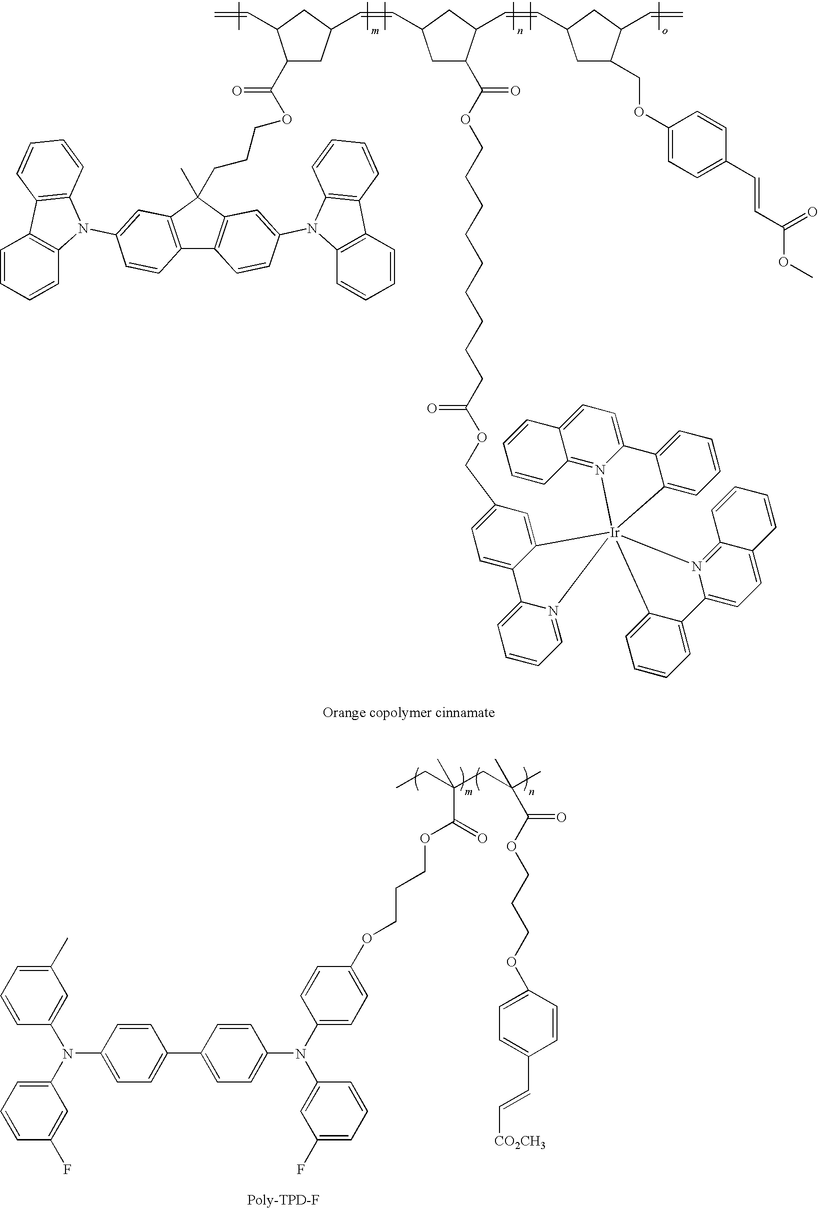

For the hole-transport layer, 10 mg of Poly-TPD-F were dissolved in 1 ml of distilled and degassed toluene. For the emissive layer, 5 mg of the crosslinkable orange copolymer with 5 mol-% Iridium content and long spacer between the Iridium complex and the polymer backbone was dissolved in 1 ml of distilled and degassed toluene. And finally, for the electron-transport layer, 10 mg of the polysilole were dissolved in 1 ml of distilled and degassed toluene. All solutions were made under inert atmosphere and were stirred overnight.

35 nm thick films of the hole-transport material were spin coated (60 s@2500 rpm, acceleration 10,000) onto air plasma treated indium tin oxide (ITO) coated glass substrates with a sheet resistance of 20 Ω/sq. (Colorado Concept Coatings, L.L.C.). Films were crosslinked using a standard broad-band UV light with a 0.7 mW/cm² power density for 1 minute. Subsequently, a 17 nm thick film of the crosslinkable orange copolymer solution was spin coated on top of the crosslinked hole-transport layer (60 s@1500 rpm, acceleration 10,000). The emissive layer was crosslinked with the same UV light at 0.7 mW/cm² power density for 30 minutes. For the electron-transport layer, a 40 nm thick film of the oxadiazole polymer solutions was spin coated on top of the crosslinked emissive layer (60 s@1500 rpm, acceleration 10,000).

Finally, 2.5 nm of lithium fluoride (LiF) as an electron-injection layer and a 200 nm-thick aluminum cathode were vacuum deposited at a pressure below 1×10⁻⁶ Torr and at rates of 0.1 Å/s and 2 Å/s, respectively. A shadow mask was used for the evaporation of the metal to form five devices with an area of 0.1 cm² per substrate. At no point during fabrication, the devices were exposed to atmospheric conditions. The testing was done right after the deposition of the metal cathode in inert atmosphere without exposing the devices to air.

The performance of the above-referenced compound is shown below in Table 6.

TABLE 6
Performance of polysilole AH-I-172 as an electron transport
layer and/or hole blocking layer. Averaged over four devices.

| | AH-I-172 |
|---|---|
| EL efficiency (cd/A) | 2 ± 1 |
| Voltage (V) | 12 |
| Quantum efficiency (%) | 1.3 ± 0.1 |

The results are based on a luminance of 100 cd/m²

Curves of the maximum luminance and external quantum efficiency (EQE) as a function of voltage for the above referenced OLED are shown in FIG. 11.

### Example 4

This example illustrates the electron mobility of the polymer XZ-III-43.

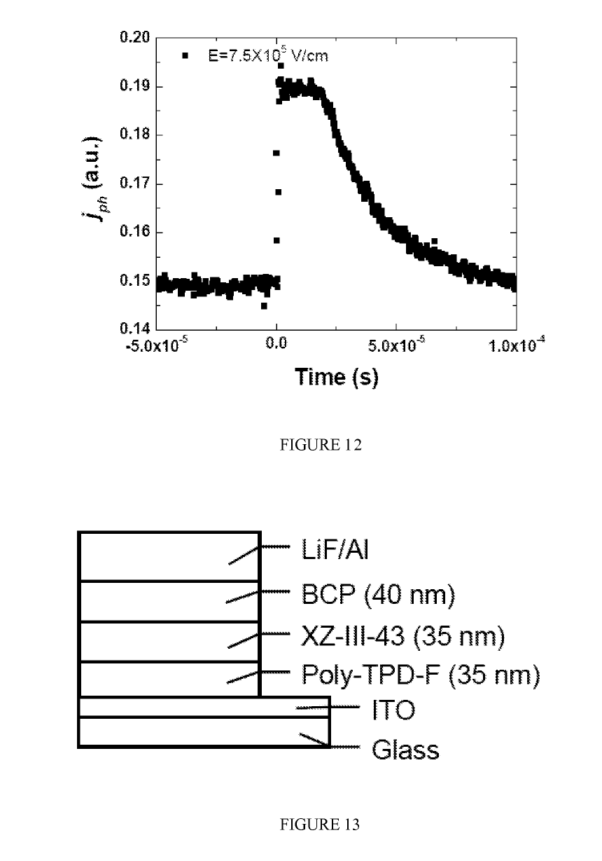

Electron mobility of the polymer was characterized using time-of-flight techniques (TOF). The polymer was melted between two ITO electrodes and a 20 μm-thick film was fabricated using calibrated glass spacers. Using ns-pulsed nitrogen laser, the sample was illuminated under an electric field and the generated transient current was measured. FIG. 12 shows a TOF transient signal obtained with an applied field of 7.5×10⁵ V/cm. The transient time can be evaluated from the transient current signal and yields an electron mobility value of 3.5×10⁻⁵ cm²/Vs. These experiments were performed in air and at room temperature.

### Example 5

This example illustrates the formation of an OLED device using a silole compound polysilole compound XZ-III-43 (of Example 2) as emissive layer. The configuration of the device is ITO/Poly-TPD-F (35 nm)/polysilole XZ-III-43 (35 nm)/BCP (40 nm)/LiF/Al and is shown in FIG. 13. BCP is shown below:

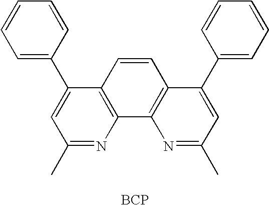

For the hole-transport layer, 10 mg of Poly-TPD-F were dissolved in 1 ml of distilled and degassed toluene. For the emissive layer, 10 mg of the polysilole XZ-III-43 were dissolved in 1 ml of distilled and degassed toluene. Both solutions were made under inert atmosphere and were stirred overnight.

35 nm thick films of the hole-transport material were spin coated (60 s@1500 rpm, acceleration 10,000) onto air plasma treated indium tin oxide (ITO) coated glass substrates with a sheet resistance of 20 Ω/sq. (Colorado Concept Coatings, L.L.C.). Films were crosslinked using a standard broad-band UV light with a 0.7 mW/cm² power density for 1 minute. Subsequently, a 35 nm thick film of the polysilole XZ-III-43 solution was spin coated on top of the crosslinked hole-transport layer (60 s@2000 rpm, acceleration 10,000). For the hole-blocking layer, bathocuproine (2,9-dimethyl-4,7-diphenyl-1,10-phenanthroline, BCP) was first purified using gradient zone sublimation, and films of 40 nm was then thermally evaporated at a rate of 0.4 Å/s and at a pressure below 1×10⁻⁷ Torr on top of the emissive layer.

Finally, 2.5 nm of lithium fluoride (LiF) as an electron-injection layer and a 200 nm-thick aluminum cathode were vacuum deposited at a pressure below 1×10⁻⁶ Torr and at rates of 0.1 Å/s and 2 Å/s, respectively. A shadow mask was used for the evaporation of the metal to form five devices with an are a of 0.1 cm² per substrate. At no point during fabrication, the devices were exposed to atmospheric conditions. The testing was done right after the deposition of the metal cathode in inert atmosphere without exposing the devices to air.

The performance of the above-reference compound is shown below in Table 8.

TABLE 8
Film thickness (35 nm)
Performance of polysilole compound XZ-III-43 as an emissive
layer. Averaged over four devices.

| | XZ-III-43 |
|---|---|
| EL efficiency | 4 ± 1 |
| (cd/A) | |
| Voltage (V) | 10.3 |
| Quantum efficiency (%) | 1.3 ± 0.1% |

The results are based on a luminance of 100 cd/m²

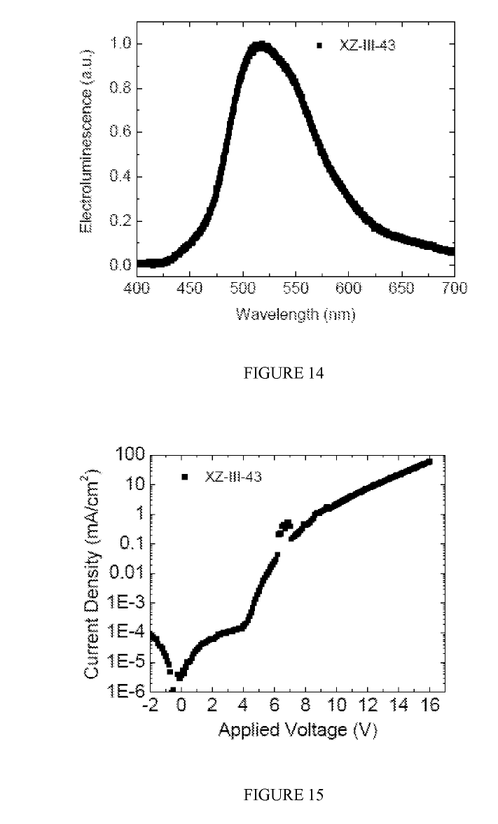

The electroluminescence spectrum of the above referenced OLED using XZ-III-43 as an emissive layer was measured with an Ocean Optics fiber spectrometer and is shown in FIG. 14.

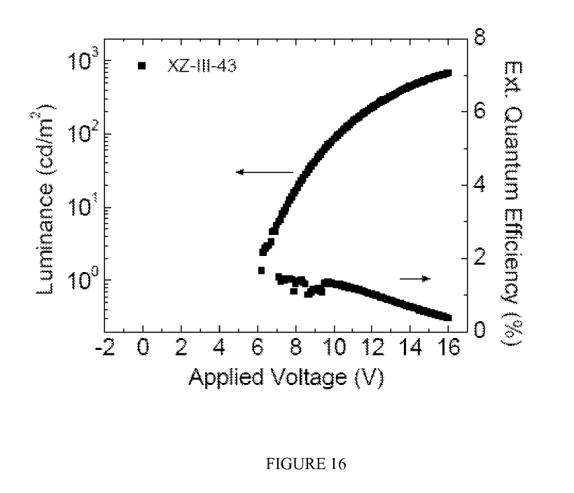

Current density-Voltage (J-V) characteristics for the above-referenced OLED devices using XZ-III-43 as an emissive layer is shown in FIG. 15. Curves of the maximum luminance and external quantum efficiency (EQE) as a function of voltage for the above referenced OLED are shown in FIG. 16.

Throughout this application, various publications are referenced. The disclosures of these publications in their entireties are hereby incorporated by reference into this application in order to more fully describe the state of the art to which this invention pertains.

While this invention has been described in terms of what are presently considered to be the most practical and preferred embodiments, it is to be understood that the invention need not be limited to the enclosed embodiment. To the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

1. A compound represented by the formula (I): 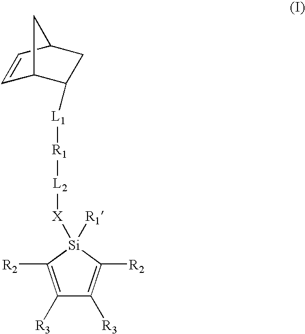
wherein:
X is arene diyl or alkane diyl, each are of which are straight chain, branched chain or cyclic, having a carbon chain length of C₁₋₂₀;
L₁, and L₂ are independently absent, or represents 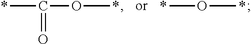
R₁ is absent or represents alkane diyl, alkene diyl, alkyne diyl, or arene diyl, each of which are straight chain, branched chain or cyclic, having a carbon chain length of C₁₋₂₀;
L₁-R₁-L₂ taken together is a linkage to the norbornene monomer, and is attached through the carbon or oxygen atom on the ester, or through the ether oxygen atom;
wherein when L₁ and L₂ are absent, then the number of carbon atoms in R₁ and X together cannot form a straight chain pentane diyl;
R₁′ is aryl; and
R₂ and R₃ are aryl.

2. The norbornene-silole compound in accordance with claim 1, wherein R₁ is an alkane diyl.

3. (canceled)

4. The compound of claim 1, wherein X is an arene diyl.

5. (canceled)

6. The compound of claim 4, wherein X is 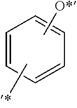
and is bound to the silole, L₁, R₁, L₂, or norbornene at the positions indicated by *′.

7. (canceled)

8. (canceled)

9. The compound of claim 1, wherein at least one of L₁ or L₂ is present.

10. The compound of claim 1, wherein L₁-R₁-L₂ taken together is 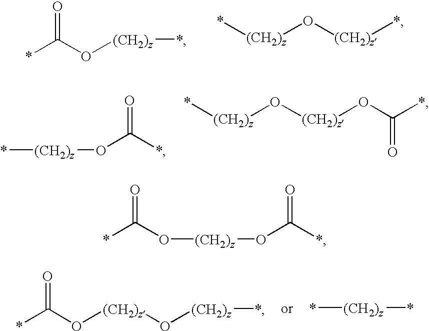
where z and z′ are independently selected integers 0, 1, 2, 3, 4, 5, 6, 7, 8, 9, 10, 11, or 12.

11-13. (canceled)

14. The norbornene-silole compound in accordance with claim 1, wherein R₂ and R₃ are both phenyl.

15. (canceled)

16. A compound represented by the formula (II): 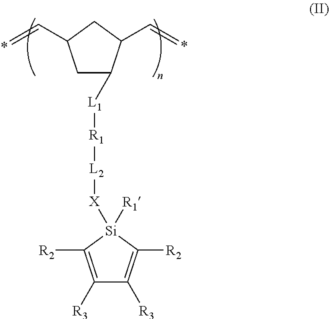
wherein:
X is arene diyl or alkane diyl, each are of which are straight chain, branched chain or cyclic, having a carbon chain length of C₁₋₂₀;
L₁, and L₂ are independently absent, or represents 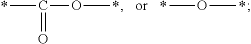
R₁ is absent or represents alkane diyl, alkene diyl, alkyne diyl, or arene diyl, each of which are straight chain, branched chain or cyclic, having a carbon chain length of C₁₋₂₀;
L₁-R₁-L₂ taken together is a linkage to the norbornene polymer, and is attached through the carbon or oxygen atom on the ester, or through the ether oxygen atom;
R₁′ is aryl;
R₂ and R₃ are aryl; and
n is an integer of from about 1 to about 2,000.

17. The compound in accordance with claim 16, wherein R₁ is an alkane diyl.

18. (canceled)

19. The compound of claim 16, wherein X is an arene diyl.

20. The compound of claim 16, where X is 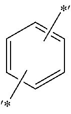
and is bound to the silole, L₁, R₁, L₂, or norbornene at the positions indicated by *′.

21. The compound of claim 16, wherein X is 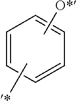
and is bound to the silole, L₁, R₁, L₂, or norbornene at the positions indicated by *′.

22. (canceled)

23. (canceled)

24. The compound of claim 16, wherein at least one of L₁ or L₂ is present.

25. The compound of claim 16, wherein L₁-R₁-L₂ taken together is 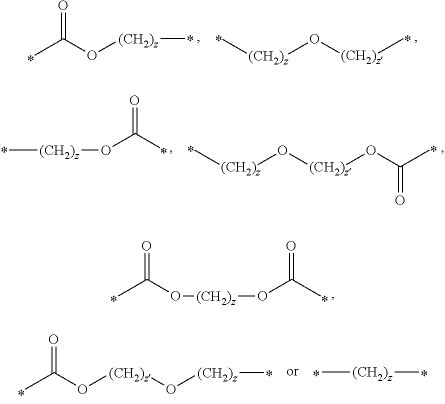
where z and z′ are independently selected integers 0, 1, 2, 3, 4, 5, 6, 7, 8, 9, 10, 11, or 12.

26-28. (canceled)

29. The compound in accordance with claim 16, wherein R₂ and R₃ are both phenyl.

30. (canceled)

31. The compound of claim 16 wherein n is 5 to 2000.

32. A device, comprising one or more of the compounds of claim 1.

33. An electron transporting and/or hole blocking layers of a device comprising one or more of the compounds of claim 16.

34. (canceled)

35. A compound having the formula

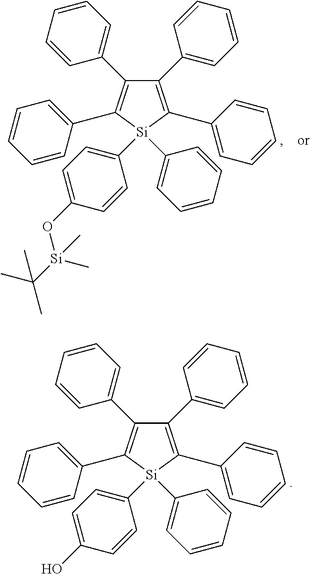

36. The compound of claim 1, having the formula: [chemical structure]
